(19) United States
(12) Patent Application Publication
(10) Pub. No.: US 2025/0194424 A1
(43) Pub. Date: Jun. 12, 2025

(54) ENERGY HARVESTER COMPRISING COMPOSITE OF PZT AND HALIDE PEROVSKITE AND METHOD FOR MANUFACTURING THE SAME

(71) Applicant: UIF (University Industry Foundation), Yonsei University, Seoul (KR)

(72) Inventors: Yong Soo CHO, Seoul (KR); Kwan Sik PARK, Seoul (KR); Da Bin KIM, Seoul (KR)

(73) Assignee: UIF (University Industry Foundation), Yonsei University, Seoul (KR)

(21) Appl. No.: 18/971,968

(22) Filed: Dec. 6, 2024

(30) Foreign Application Priority Data
Dec. 11, 2023 (KR) 10-2023-0179145
Dec. 4, 2024 (KR) 10-2024-0178690

(51) Int. Cl. H10N 30/092; H10K 85/50; H10N 30/85; H10N 30/853

(52) U.S. Cl. CPC H10N 30/092; H10K 85/50; H10N 30/852; H10N 30/8536; H10N 30/8542; H10N 30/8554

(57) ABSTRACT

The present invention provides a composite of oxide-based piezoelectric nanoparticles and a halide perovskite, which is prepared from a mixed solution in which the oxide-based piezoelectric nanoparticles are dispersed in an ABX₃ halide perovskite solution, A is an organic or inorganic cation, B is a metal cation, and X is a halogen anion. The oxide-based piezoelectric nanoparticles include at least one of PZT, BaTiO₃, and Na_{0.5}K_{0.5}NbO₃ (NKN). B includes at least one of Pb and Sn. X includes at least one of I, Br, and Cl.

### CROSS-REFERENCE TO RELATED APPLICATION

This application claims priority to and the benefit of Korean Patent Application Nos. 10 2023-0179145, filed on Dec. 11, 2023, and 10-2024-0178690 filed on Dec. 4, 2024, the disclosure of which are incorporated herein by reference in its entirety.

### BACKGROUND

The present invention relates to an energy harvester, which is composed of a ceramic-matrix composite of perovskite oxide and perovskite halide.

Energy harvesting refers to the technology of harvesting energy generated from natural energy sources such as solar light, pressure, heat, and wind power and converting it into electrical energy.

Such energy harvesting is attracting attention as an eco-friendly energy utilization technology that can maintain the stability, security, and sustainability of energy supply and reduce environmental pollution because it enables electrical energy to be directly obtained from nature.

A halide perovskite (HPV) compound is a material with a structure represented by ABX₃, wherein A is an organic or inorganic cation, B is a metal cation such as Pb or Sn, X is a halogen anion, and B and X form an octahedron called BX₆. In addition, B is located at the center of the octahedron formed by X located at the corners, the octahedron forms a three-dimensional network with all corners connected to each other, and A is a material whose structure balances the charge of the entire network with large cations that fill the empty holes created by adjacent octahedra within the three-dimensional structure. The organic cations used in this material are mostly methylammonium cations (CH3NH₃⁺, or MA⁺), but may also be formamidinium cations (HC(NH₂)₂⁺, or FA⁺) or Cs⁺. B is a divalent metal, such as Pb, Sn, or Cu.

Piezoelectric devices are materials that can convert electrical energy into mechanical energy and vice versa, and are used in various sensors, generators, transducers, and actuators.

Lead titanate zirconate (PZT), a solid solution of zirconate (PbZrO₃) and titanate (PbTiO₃), is a representative perovskite oxide material that is widely used in piezoelectric devices. The dielectric constant, piezoelectric constant, and electromechanical coupling constant reach the maximum levels at the phase transition point near the equal contents of Zr and Ti in the solid solution. PZT is a representative piezoelectric ceramic and is used in the wide range of electromechanical devices including actuators, frequency filters, pressure sensors, etc. PZT has the advantage of high piezoelectricity, but has the disadvantage of being difficult to produce in the form of a thin film at low temperatures, which avoids the use of polymer substrates for flexible electronic systems.

### SUMMARY

The present invention is directed to producing a thin-film-based composite energy harvester processed at low temperatures, consisting of perovskite oxide as a filler and perovskite halide as a matrix.

According to one aspect of the present invention, a method of producing an energy harvester including a composite of perovskite PZT and perovskite halide, which includes: preparing a first mixed solution in which PbI₂ and MAI are dissolved; preparing a second mixed solution by introducing PZT particles surface-treated with polyethylene glycol; PEG) to the first mixed solution; and forming a thin film using the second mixed solution, is provided.

According to another aspect of the present invention, an energy harvester including a composite of PZT and a halide perovskite, produced by the above-described production method, is provided.

According to still another aspect of the present invention, a composite of oxide-based piezoelectric nanoparticles and a halide perovskite is provided. The composite is prepared from a mixed solution in which the oxide-based piezoelectric nanoparticles are dispersed in an ABX₃ halide perovskite solution, where A is an organic or inorganic cation, B is a metal cation, and X is a halogen anion.

According to the present invention, an energy harvester which can be produced in a thin film at low temperatures may be provided by forming a composite consisting of PZT particles in a halide perovskite matrix may be provided.

### BRIEF DESCRIPTION OF THE DRAWINGS

FIG. 1 is a diagram illustrating a method of producing an energy harvester that includes a composite of PZT particles embedded in a MAPbI₃ matrix according to one embodiment of the present invention.

FIG. 2 is a schematic diagram of an energy harvester according to one embodiment of the present invention.

FIG. 3 shows FE-SEM images of MAPbI₃ and PZT-MAPbI₃ (20 vol %) according to one embodiment of the present invention.

FIG. 4 shows a butterfly loop regarding the PFM PR characteristics of a PZT-MAPbI₃ thin film according to one embodiment of the present invention.

FIG. 5 shows the maximum voltage and maximum current according to one embodiment of the present invention.

FIG. 6 shows the output voltage and output current when a poling field according to one embodiment of the present invention is applied.

FIG. 7 is a graph evaluating the harvesting stability of a 20 vol % PZT-MAPbI₃ thin film that had been poled according to the bending cycle of the PZT-MAPbI₃ thin film according to one embodiment of the present invention.

### DETAILED DESCRIPTION

The above objects, other objects, features and advantages of the present invention will be easily understood through the following exemplary embodiments relating to the accompanying drawings. The present invention is not limited to exemplary embodiments to be described below, but may be embodied in other forms. Rather, the embodiments presented herein are provided such that the technical idea can be fully conveyed to those of ordinary skill in the art.

In description of each drawing, like numerals denote like elements. In the accompanying drawings, the dimensions of structures are enlarged from the actual size for the clarity of the present invention. The terms “first” and “second” may be used to describe various components, but the components should not be limited by these terms. The terms are used only to distinguish one component from another component. For example, without departing from the scope of the present invention, a first component may be referred to as a second component, and similarly, a second component may also be referred to as a first component. Singular expressions include plural referents unless the context clearly indicates otherwise.

In the specification, it should be understood that the term “comprise,” “include,” or “have” is intended to indicate the presence of a characteristic, number, step, action, component or part described in the specification, or a combination thereof, but does not preclude the possibility of the presence or addition of one or more other characteristics, numbers, steps, actions, components, parts or a combination thereof. In addition, when a part of a layer, film, region or plate is disposed “on” another part, this includes not only a case in which one part is disposed “directly on” the other part, but also a case in which a third part is interposed therebetween. In contrast, when a part of a layer, film, region or plate is disposed “under” another part, this includes not only a case in which the one part is disposed “directly under” the other part, but also a case in which a third part is interposed therebetween. In addition, in this application, “on” may include not only a case in which something is disposed on an upper part of something else but also a case in which something is disposed on a lower part of something else.

Unless otherwise specified, all numbers, values, and/or expressions that express components, reaction conditions, chemical compositions, and the amount of a mixture, used in the specification, are to be understood as being modified in all instances by the term “approximately” since these numbers are approximations that reflect the various uncertainties of measurement occurring to obtain these values, among other things. In addition, when a numerical range is disclosed in this description, such range is continuous and, unless indicated otherwise, includes all values from the minimum value to the maximum value. Furthermore, when such a range refers to an integer, unless otherwise indicated, all integers from the minimum value up to the maximum value are included.

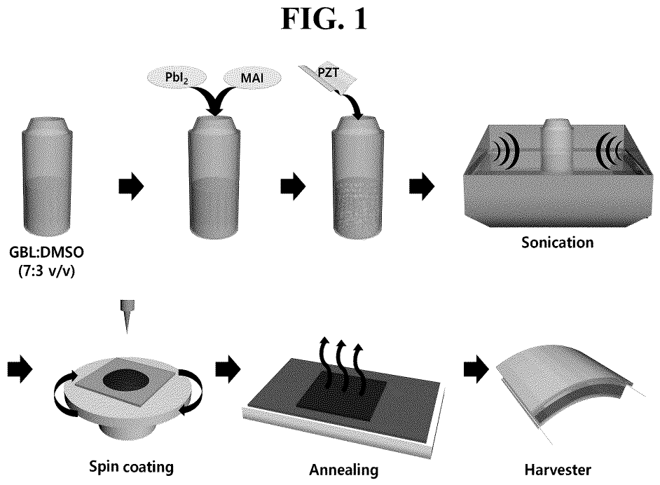

FIG. 1 is a diagram illustrating a method of producing an energy harvester that includes a composite of PZT and MAPbI₃ according to one embodiment of the present invention.

Referring to FIG. 1, the method of producing an energy harvester that includes a composite of PZT and a halide perovskite according to one embodiment of the present invention includes preparing a first mixed solution in which PbI₂ and MAI are dissolved; preparing a second mixed solution by introducing PZT nanoparticles whose surface is treated with PEG to the first mixed solution; and forming a thin film using the second mixed solution.

According to one embodiment of the present invention, in the step of preparing a first mixed solution in which PbI₂ and MAI are dissolved, PbI₂ and MAI may be added to the mixed solvent of dimethylsulfoxide and γ-butyrolactone.

According to one embodiment of the present invention, the concentration of PbI₂ added to the mixed solvent may range from 1.3 to 1.7 M. Beyond the above range, when the concentration of PbI₂ is too low, the thin film is too thin, and there is the disadvantage that it is difficult to form the composite thin film, and when the concentration of PbI₂ is too high, there is the disadvantage that it is difficult to form the thin film due to the limited solubility of the solution.

According to one embodiment of the present invention, the volume ratio of dimethylsulfoxide and γ-butyrolactone in the mixed solvent may range from 2:8 to 4:6.

According to one embodiment of the present invention, in the step of preparing a second mixed solution by introducing PZT particles whose surface is treated with PEG to the first mixed solution, the amount of PZT particles added may be greater than 0 vol % and less than or equal to 20 vol % with respect to the MBPbI₃ solution.

According to one embodiment of the present invention, in the step of preparing a second mixed solution by introducing PZT nanoparticles whose surface is treated with PEG to the solution, the dispersity of the PZT nanoparticles may increase through PEG surface treatment, and a thin film of a high quality PZT-halide perovskite composite (PZT-MAPbI₃ composite) may be formed.

According to one embodiment of the present invention, the step of forming the thin film may be performed by spin-coating the second mixed solution.

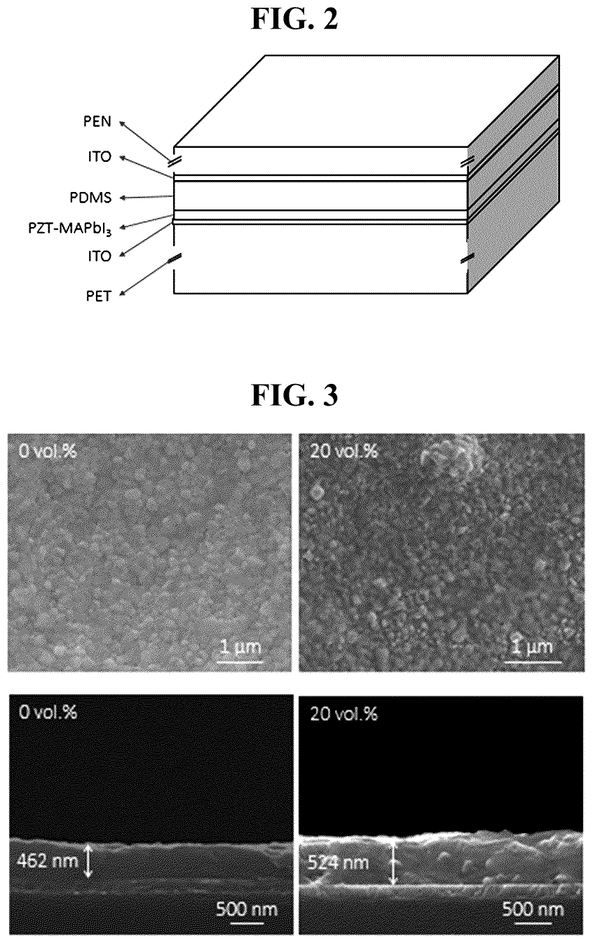

FIG. 2 is a schematic diagram of an energy harvester according to one embodiment of the present invention.

Referring to FIG. 2, the energy harvester according to one embodiment of the present invention may have a stacked structure with a plurality of layers.

According to one embodiment of the present invention, the stacked structure may be formed by stacking ITO/PET, PZT-MAPbI₃, PDMS, and ITO/PEN in that order.

According to one embodiment of the present invention, the stacked structure may include the PZT-halide perovskite composite (PZT-MAPbBI₃), ITO/PET disposed at one side of a PZT-halide perovskite composite (PZT-MAPbI₃), PDMS disposed at the other side of the PZT-halide perovskite composite (PZT-MAPbI₃), and ITO/PEN disposed at a side opposite to one side of the PDMS where the composite of PZT and a halide perovskite is disposed (PZT-MAPbI₃).

A composite of oxide-based piezoelectric nanoparticles and a halide perovskite according to one embodiment of the present invention may be prepared from a mixed solution in which oxide-based piezoelectric nanoparticles are dispersed in an ABX₃ halide perovskite solution. Here, A may be an organic cation, B may be a metal cation, and X may be a halogen anion.

According to one embodiment of the present invention, the oxide-based piezoelectric nanoparticles may include at least one of PZT, BaTiO₃, and Na_{0.5}K_{0.5}NbO₃ (NKN).

According to one embodiment of the present invention, B may include at least one of Pb and Sn.

According to one embodiment of the present invention, X may include at least one of I, Br, and Cl.

The composite of PZT and a halide perovskite according to one embodiment of the present invention is a composite of PZT and a halide perovskite, which is prepared from a PZT-MAPbI₃ solution in which PZT particles are dispersed in an MAPbI₃ solution. The volume fraction of the PZT particles may be greater than 0 vol % and less than or equal to 20 vol % with respect to the volume of the PZT-MAPbI₃ solution.

By controlling the volume fraction of the PZT particles, a PZT-halide perovskite composite in which PZT nanoparticles are uniformly dispersed and a thin film produced therefrom may be obtained. When the volume fraction of the PZT particles is greater than 20 vol %, uniform dispersion of the particles is difficult to achieve, and surface roughness increases due to agglomeration, making it difficult to obtain a uniform PZT-halide perovskite composite and a thin film produced therefrom.

According to one embodiment of the present invention, the MAPbI₃ solution may be prepared by dissolving lead iodide (PbI₂) and methyl ammonium iodide (MAI) in the mixed solvent of dimethylsulfoxide (DMSO) and γ-butyrolactone (C₄H₆O₂).

According to one embodiment of the present invention, the volume ratio of dimethylsulfoxide (DMSO) and γ-butyrolactone (C₄H₆O₂) in the mixed solvent may be 3:7. By adjusting the above volume ratio, the solubility of MAI and PbI₂ may be adjusted and the crystallization quality of the thin film produced from the PZT-halide perovskite composite may be determined. When the volume ratio is not 3:7, it may affect the evaporation rate and crystallization of the solution, reducing the uniformity and quality of the thin film produced during spin coating using the PZT-halide perovskite composite.

According to one embodiment of the present invention, as the volume fraction of the PZT particles increases, the piezoresponse (PR) amplitude may increase.

### Experimental Examples

The present invention will be described more specifically through the following experimental examples. The following experimental examples are merely examples to help understand the present invention, and the scope of the present invention is not limited thereto.

### 1. Preparation of PZT Particles

In the experimental example, to synthesize nanoparticles, the composition of Pb(Zr_{0.5}Ti_{0.5})O₃ was selected. Lead acetate trihydrate (Pb(CH₃COO)₂·3H₂O, Kanto, Japan), zirconium propoxide (Zr(OCH₂CH₂CH₃)₄, Sigma-Aldrich), and titanium isopropoxide (Ti[(CH₃)₂CHO]₄, Sigma-Aldrich) were used.

First, to compensate for the potential loss of Pb that can occur in combustion, more than 20% lead acetate trihydrate was dissolved in 2-methoxyethanol (CH₃OCH₂CH₂OH, Sigma-Aldrich) while stirring at 125° C. for 1 hour. The sources of Zr and Ti were dissolved separately in 2-methoxyethanol while stirring at 80° C. for 1 hour.

To maintain a transparent common solution of all elements, the Pb solution was slowly dropped into a Zr—Ti precursor solution.

Polyacrylic acid (PAA:(C₃H₄O)ₙ, Sigma-Aldrich), which serves as a fuel for a combustion reaction, was additionally dissolved in the precursor solution. The relative amount of PAA was fixed as R=1.0, where R is the atomic ratio between the number of carboxyl ions of PAA and the total number of metal ions of PZT.

Then, the PAA solution was completely dried at 120° C. for 6 hours, thereby obtaining a dried gel.

The dried gel was synthesized by combustion in a box furnace at 650° C. for 2 hours, thereby obtaining a nano-sized powder.

2. Preparation of MAPbI₃ Thin Film from PZT Particles

A flexible MAPbI₃-PZT thin film was prepared on a 125 μm ITO/PET substrate through a one-step deposition procedure. To deposit the PZT-MAPbI₃ thin film, a PZT-MAPbI₃ precursor was prepared by dissolving 1.5 M lead iodide (PbI₂, 99.99%, TCI, Japan) and methyl ammonium iodide (MAI, 99.9%, Greatcell Solar Materials, Australia) in a mixed solvent (volume ratio=3:7) of dimethylsulfoxide (DMSO:(CH₃)₂SO, 99.9%, Sigma-Aldrich Inc, USA) and γ-butyrolactone (C₄H₆O₂, 99.9%, Sigma-Aldrich, USA), and stirred at room temperature for 3 hours, thereby obtaining a transparent light-yellow solution.

After dissolving PbI₂ and MAI, 0 to 20 vol % of PZT particles were added to the MAPbI₃ solution and sonicated for 30 minutes to disperse the PZT particles. Before deposition of the PZT-MAPbI₃ thin film, the 2.5×2.5 ITO/PET substrate was sonicated in an IPA bath for 15 minutes and dried in an oven, and then the surface of the substrate was treated with 02 plasma at 100 W for 5 minutes.

The PZT-MAPbI₃ precursor was spin-coated on the ITO/PET substrate at 3000 rpm for 30 seconds, and 2 mL of toluene was applied as an anti-solvent.

After spin-coating, the resulting product was annealed at 75° C. for 10 minutes.

### 3. Preparation of Piezoelectrical Energy Harvester

A piezoelectrical energy harvester was produced by covering the deposited PZT-MAPbI₃ film with an ITO/PEN substrate coated with another PDMS layer. A 50 μm ITO/PEN substrate was coated with a PDMS (SYLGARD 184, Dow Corning, USA) solution consisting of a base monomer containing a 10 wt % curing agent through spin coating at 4000 rpm for 30 seconds, precured at 100° C. for 3 minutes, attached to the PZT-MAPbI₃ film, and cured at 70° C. for a long period of time to remove a potential gap between the PDMS and the halide film. The completed harvester had the structure of PEN/ITO/PDMS/PZT-MAPbI₃/ITO/PET with an effective area of 5 cm². Cu wires were externally connected to both sides of the ITO layer, and the harvester was passivated with a PI tape.

### 4. Measurement and Characterization

The crystal structure of an in-situ strained PZT-MAPbI₃ film was examined using an X-ray diffractometer (SmartLab, Rigaku, Japan) operating in scan step mode with a step size of 0.01° and a dwell time of 2 seconds/step over a scan range of 10 to 50° at an incident angle of 0.5°.

FIG. 3 shows FE-SEM images of MAPbI₃ and PZT-MAPbI₃ (20 vol %) according to one embodiment of the present invention.

Referring to FIG. 3, the surface and cross-sectional images were obtained using a field-emission scanning electron microscope (FE-SEM; (JSM-7001F, JEOL, Japan).

The piezoelectric properties of the halide film were characterized by PFM (Nanoscope V Multimode, Broker, USA) using conductive Pt/Ir-coated Si cantilever tips. The PR amplitude was measured by scanning the film surface (3 μm×3 μm) with a driving amplitude of 4 V in the lock-in mode at a variable AC voltage (Vac). The effective out-of-plane piezoelectric coefficient (d_{33,eff}) was estimated from the peak amplitude using the relationship A_{deflection}=d_{33,eff}×Vac/16, where A_{deflection} is the peak amplitude.

The harvesting performance was evaluated under cyclic bending in a frequency range of 0.5 to 3.5 Hz and bending strains of 0.18 to 0.62% using a single-axis high-speed fatigue machine (CTLM500, Ceratorq, Korea). The output performance was measured using a nanovoltmeter (Keithley 2182A, ValueTronics, USA) operating at an internal resistance of 10 MΩ, and the output current was determined using a galvanostat system (IviumStat, Ivium Technologies, Netherlands) operating at an internal resistance of 1 MΩ. To calculate the power density for the optimal harvester, the output voltage was measured by varying the resistive load (RL) in the range of 10² to 10⁷Ω.

### 5. Analysis of Piezoforce Microscopy (PFM) for PZT-MAPbI₃ Thin Film

The effect of PZT nanoparticle inclusion on piezoelectricity was observed via piezoforce microscopy (PFM).

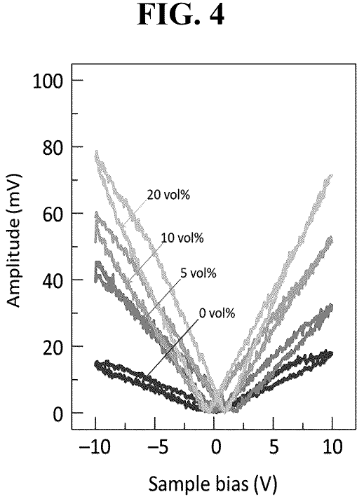

FIG. 4 shows a butterfly loop regarding the PFM PR characteristics of a PZT-MAPbI₃ thin film according to one embodiment of the present invention.

Referring to FIG. 4, a PR response was measured under DC bias ranging from −10 V to +10 V. The d₃₃ value measured by PFM was shown to increase as the content of PZT (vol %) increased.

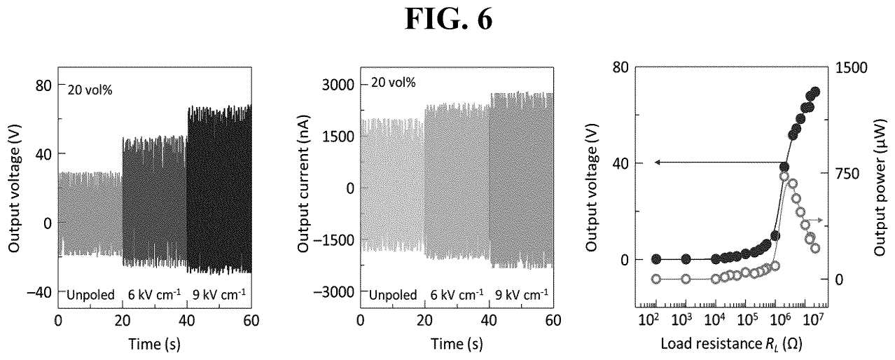

In addition, referring to FIG. 6, it can be seen that, the d_{33,eff} value calculated based on the amplitude obtained by PFM measurement increased to 9.93 pm/V at 0 vol % and 43.6 pm/V at 20 vol %.

### 6. Output Performance of PZT-MAPbI₃ Energy Harvester

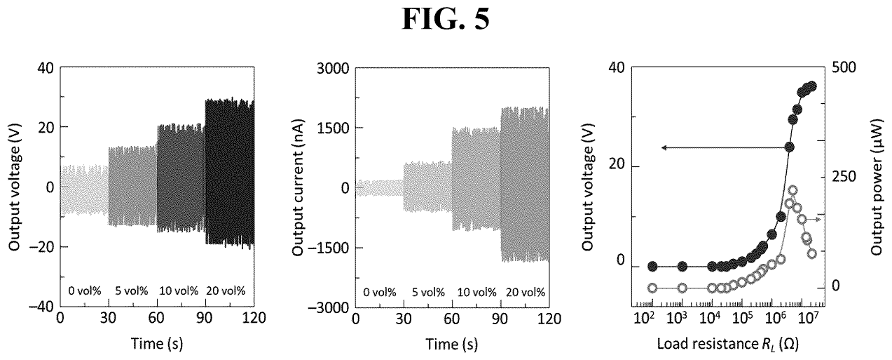

FIG. 5 shows the output voltage and output current according to one embodiment of the present invention.

Referring to FIG. 5, the output voltage and current according to various PZT volume fractions were obtained at a bending strain of 0.61% and a frequency of 3.1 Hz. The peak output voltage and current gradually increased from 9.5 V and 204 nA to 32.7 V and 1793 nA as the PZT content increased from 0 to 20 vol %. These results are consistent with the previously mentioned d_{33,eff} values and PR amplitude distributions, confirming that the output performance increases with increasing volume fraction of PZT nanoparticles.

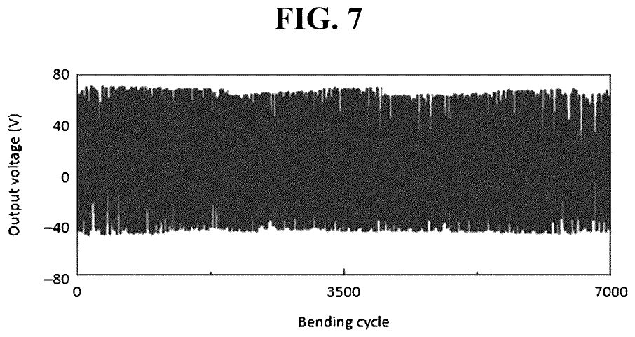

In addition, referring to FIG. 5, the resistive load-dependent harvesting performance of a 20 vol % sample with a peak output power of 212.2 μW at 5.1 MΩ is shown. Table 1 below is a table analyzing the data shown in FIG. 7.

TABLE 1

| PZT vol % | 0 | 5 | 10 | 20 |
|---|---|---|---|---|
| Max Voltage (V) | 9.5 | 13.9 | 23.1 | 32.7 |
| Max current (nA) | 204 | 762 | 1510 | 1793 |
| Power (μW) | | | | 212.2 (5.1 MΩ) |

FIG. 6 shows the output voltage and output current when a poling field according to one embodiment of the present invention is applied.

Referring to FIG. 6, to further improve energy harvesting performance, dipoles were aligned by applying an electric field to the 20 vol % sample. After increasing the poling fields, for MAPbI₃ using the 20 vol % PZT sample, the output voltage and current values were shown to increase from 32.7 V to 52.2 V and 68.9 V, and from 1793 nA to 2496 nA and 2733 nA, respectively.

In addition, referring to FIG. 6, the harvesting performance according to the resistive load after poling is shown, indicating a peak output power of 725.5 μW at 5.1 MΩ. Table 2 below is a table analyzing the data shown in FIG. 6.

TABLE 2

| PZT vol % | 20 vol % | | |
|---|---|---|---|
| Poling field (kV cm⁻¹) | 0 | 6 | 9 |
| Max. voltage (V) | 32.7 | 52.2 | 68.9 |
| Max. current (nA) | 1793 | 2496 | 2733 |
| Power (μW) | 212.2 (5.1 MΩ) | — | 725.5 (5.1 MΩ) |

FIG. 7 is a graph evaluating the harvesting stability of a 20 vol % PZT-MAPbI₃ thin film that had been poled according to the bending cycle of the PZT-MAPbI₃ thin film according to one embodiment of the present invention.

Referring to FIG. 7, it can be seen that the stability is maintained even after bending 7000 times or more through the stability test evaluated at a bending strain of 0.71% and a bending frequency of 3.12 Hz.

Although the present invention has been described above with reference to the preferred embodiments thereof, it will be understood by those of ordinary skill in the art that various modifications and changes may be made to the present invention without departing from the spirit and scope of the present invention as set forth in the claims below.

1. A method of producing an energy harvester including a composite of PZT and a halide perovskite, comprising:
preparing a first mixed solution in which PbI₂ and MAI are dissolved;
preparing a second mixed solution by introducing PZT particles whose surface is treated with PEG to the first mixed solution; and
forming a thin film using the second mixed solution.

2. The method of claim 1, wherein the preparing of a first mixed solution in which PbI₂ and MAI are dissolved includes
adding PbI₂ and MAI to the mixed solvent of dimethylsulfoxide and γ-butyrolactone.

3. The method of claim 2, wherein the concentration of PbI₂ added to the mixed solvent ranges from 1.3 to 1.7 M.

4. The method of claim 2, wherein the volume ratio of dimethylsulfoxide and γ-butyrolactone in the mixed solvent ranges from 2:8 to 4:6.

5. The method of claim 1, wherein, in the preparing of a second mixed solution by introducing PZT particles surface-treated with PEG to the first mixed solution, the amount of PZT particles added is greater than 0 vol % and less than or equal to 20 vol % with respect to the first mixed solution.

6. An energy harvester comprising a composite of PZT and a halide perovskite, which is produced by the production method of claim 1.

7. The energy harvester of claim 6, further comprising:
ITO/PET disposed on one side of the composite of PZT and a halide perovskite;
PDMS disposed on the other side of the composite of PZT and a halide perovskite; and
ITO/PEN disposed on a side opposite to the one side of the PDMS on whichi the composite of PZT and a halide perovskite is disposed.

8. A composite of oxide-based piezoelectric nanoparticles and a halide perovskite, which is prepared from a mixed solution in which oxide-based piezoelectric nanoparticles are dispersed in an ABX₃ halide perovskite solution,
wherein A is an organic cation, B is a metal cation, and X is a halogen anion.

9. The composite of claim 8, wherein the oxide-based piezoelectric nanoparticles include at least one of PZT, BaTiO₃, and Na_{0.5}K_{0.5}NbO₃ (NKN).

10. The composite of claim 8, wherein B includes at least one of Pb and Sn.

11. The composite of claim 8, wherein X includes at least one of I, Br, and Cl.

12. The composite of claim 8, wherein, in the composite of PZT and a halide perovskite prepared from a PZT-MAPbI₃ solution in which PZT particles are dispersed in an MAPbI₃ solution,
the volume fraction of the PZT particles is greater than 0 vol % and less than or equal to 20 vol % with respect to the volume of the PZT-MAPbI₃ solution.

13. The composite of claim 12, wherein the MAPbI₃ solution is prepared by dissolving lead iodide (PbI₂) and methyl ammonium iodide (MAI) in the mixed solvent of dimethylsulfoxide (DMSO) and γ-butyrolactone (C₄H₆O₂).

14. The composite of claim 13, wherein the volume ratio of dimethylsulfoxide (DMSO) and γ-butyrolactone (C₄H₆O₂) in the mixed solvent is 3:7.

15. The composite of claim 12, wherein, as the volume fraction of the PZT particles increases, the piezoresponse (PR) amplitude of the composite increases.
